(19) United States
(12) Patent Application Publication
(10) Pub. No.: US 2005/0019963 A1
(43) Pub. Date: Jan. 27, 2005

(54) Maintaining a reactor chamber of a chemical vapor deposition system

(75) Inventors: Jin Zhao, Plano, TX (US); Nathan J. Kruse, McKinney, TX (US); Ignacio Blanco, Allen, TX (US); Mercer L. Brugler, Flower Mound, TX (US)

Correspondence Address: TEXAS INSTRUMENTS INCORPORATED, P O BOX 655474, M/S 3999, DALLAS, TX, 75265, US

(73) Assignee: Texas Instruments Incorporated

(21) Appl. No.: 10/623,757

(22) Filed: Jul. 21, 2003

(51) Int. Cl. C23C 16/00; H01L 21/66; C25F 1/00; C25F 5/00; H01L 21/31

(52) U.S. Cl. 438/14; 427/237; 427/248.1; 438/778; 134/1.2; 438/905

(57) ABSTRACT

Maintaining a reactor chamber of a chemical vapor deposition system includes depositing layers on an inner surface of the reactor chamber, where the layers form an accumulation layer. When the accumulation layer reaches a specified thickness, a plasma clean cycle is performed by introducing cleaning gas into the reactor chamber. The volume of the cleaning gas used during one or more plasma clean cycles is calculated, where the volume indicates the volume of cleaning gas introduced into the reactor chamber. A notification is provided when the volume of the cleaning gas used during the plasma clean cycles has reached a predetermined volume.

### TECHNICAL FIELD OF THE INVENTION

This invention relates generally to the field of semiconductor devices and more specifically to maintaining a reactor chamber of a chemical vapor deposition system.

### BACKGROUND OF THE INVENTION

Chemical vapor deposition (CVD) reactor chambers are used to form layers on semiconductor wafers according to a chemical vapor deposition procedure. During the procedure, an accumulation may be deposited on an inner surface of a reactor chamber. The accumulation may be removed with a cleaning process. According to known techniques for maintaining a reactor chamber, however, the cleaning process may result in an undesirable amount of particles in the chemical vapor deposition reactor chamber. Consequently, known techniques for maintaining a chemical vapor deposition reactor chamber may be unsatisfactory in certain situations.

### SUMMARY OF THE INVENTION

In accordance with the present invention, disadvantages and problems associated with previous techniques for maintaining a chemical vapor deposition reactor chamber may be reduced or eliminated.

According to one embodiment of the present invention, maintaining a reactor chamber of a chemical vapor deposition system includes depositing layers on an inner surface of the reactor chamber, where the layers form an accumulation layer. When the accumulation layer reaches a specified thickness, a plasma clean cycle is performed. The volume of the cleaning gas used during one or more plasma clean cycles is calculated, where the volume indicates the volume of cleaning gas introduced into the reactor chamber. A notification is provided when the volume of the cleaning gas used during the plasma clean cycles has reached a predetermined volume.

Certain embodiments of the invention may provide one or more technical advantages. A technical advantage of one embodiment may be that the volume of cleaning gas introduced into a reactor chamber during one or more cleaning cycles may be used to schedule chamber maintenance. The volume of cleaning gas may provide a relatively accurate estimate of when the reactor chamber may need chamber maintenance.

Certain embodiments of the invention may include none, some, or all of the above technical advantages. One or more other technical advantages may be readily apparent to one skilled in the art from the figures, descriptions, and claims included herein.

### BRIEF DESCRIPTION OF THE DRAWINGS

For a more complete understanding of the present invention and its features and advantages, reference is now made to the following description, taken in conjunction with the accompanying drawings, in which:

FIG. 1 is a diagram illustrating an example of a chemical vapor deposition (CVD) system that includes one embodiment of a plasma clean apparatus for maintaining a reactor chamber of the chemical vapor deposition system;

FIG. 2 is a flowchart demonstrating one embodiment of a method that may be used to maintain a reactor chamber of the chemical vapor deposition system; and

FIGS. 3 and 4 are example graphs indicating relative inline oxide defect densities (DD) with respect to a nitrogen trifluoride (NF₃) flow time.

### DETAILED DESCRIPTION OF THE DRAWINGS

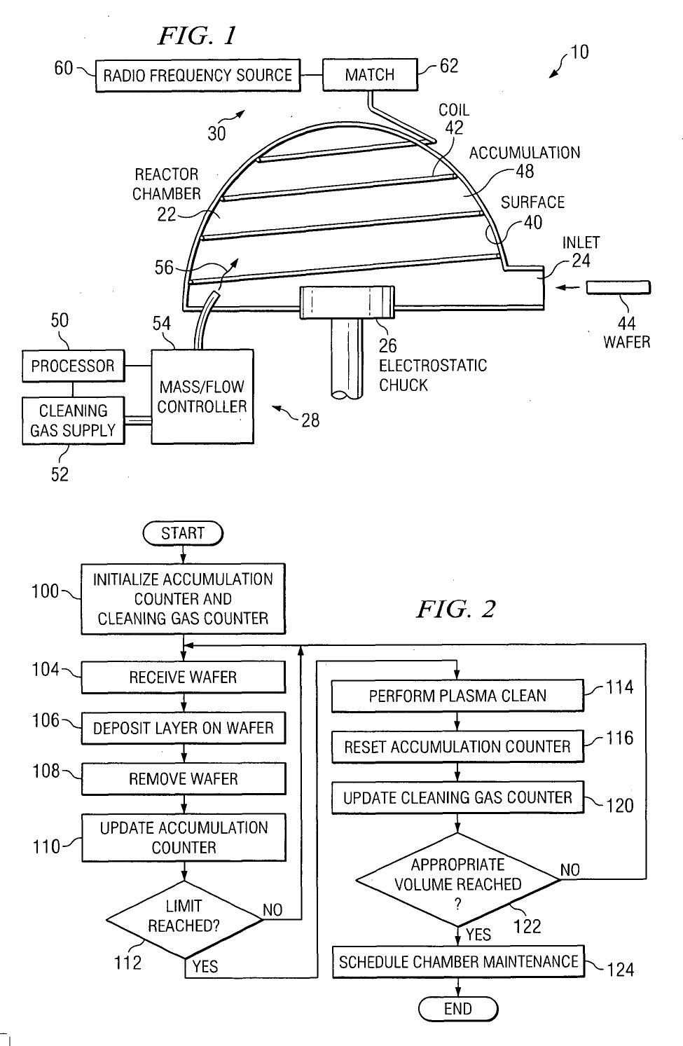

Embodiments of the present invention and its advantages are best understood by referring to FIGS. 1 through 4 of the drawings, like numerals being used for like and corresponding parts of the various drawings.

FIG. 1 is a diagram illustrating a chemical vapor deposition (CVD) system 10 that includes one embodiment of a plasma clean apparatus 28 for maintaining a reactor chamber 22 of chemical vapor deposition system 10. As the chemical vapor deposition procedure is performed, an accumulation may be formed on an inner surface of reactor chamber 22, which may be cleaned using a cleaning gas. According to the embodiment, plasma clean apparatus 28 may determine the volume of cleaning gas that is introduced into reactor chamber 22 during one or more cleaning cycles in order to establish when chamber maintenance should be performed on reactor chamber 22.

According to one embodiment, system 10 may be used to perform a chemical vapor deposition procedure in order to deposit layers of a material outwardly from an outer surface of a target such as a semiconductor wafer. The deposited layer may have a thickness ranging from, for example, 1.8 kiloAngstroms to 12.5 kiloAngstroms. During the process, a carrier chemical that includes atoms of the material to be deposited on the wafer reacts with another reactant chemical, depositing the product of the chemical reaction on the wafer. Unwanted byproducts of the reaction may be removed through subsequent process steps.

The relative concentration of the carrier chemical and the reactant chemical within reactor chamber 22 may be varied. Other parameters within reactor chamber 22 may also be varied, for example, the temperature and pressure inside of reactor chamber 22 and the time that the wafer is exposed to the chemicals. Examples of deposition procedures performed by system 10 may include fluorinated silicate glass (FSG), shallow trench isolation (STI), undoped silicate glass (USG), phosphoric silicate glass (PSG), or silicone nitride procedures.

According to the illustrated embodiment, chemical vapor deposition system 10 includes reactor chamber 22, an inlet 24, an electrostatic chuck 26, a plasma clean apparatus 28, and a radio frequency power generating system 30 coupled as shown in FIG. 1. Reactor chamber 22 may comprise a substantially hemispherical shaped dome having an inner surface 40. A coating may be disposed outwardly from surface 40 of reactor chamber 22. The coating may comprise any suitable material, for example, aluminum oxide. One or more coils operable to conduct a radio frequency power through reactor chamber 22 may be coupled to reactor chamber 22. An inlet 24 may be used to introduce a wafer 44 into reactor chamber 22. Wafer 44 may be mechanically placed by a robotic arm onto electrostatic chuck 26. Electrostatic chuck 26 may be operable to hold wafer 44 into position during the chemical vapor deposition procedure.

As chemical vapor deposition system 10 deposits layers on wafer 44, an accumulation 48 may be deposited outwardly from inner surface 40 of reactor chamber 22. Accumulation 48 may comprise, for example, an oxide formed as the reactant chemical reacts with inner surface 40 of reactor chamber 22. If accumulation 48 becomes too thick, for example, greater than four microns such as six microns, accumulation 48 may start to flake and create defects at wafer 44. Before accumulation 48 reaches a thickness at which it is prone to flaking, reactor chamber 22 may be cleaned to remove accumulation 48. As an example, during fluorine doped silicate glass deposition, reactor chamber 22 may be cleaned when accumulation 48 reaches a thickness of approximately six microns. According to one embodiment, plasma clean apparatus 28 may include components operable to introduce cleaning chemicals into reactor chamber 22.

Plasma clean apparatus 28 performs a cleaning process in order to substantially remove accumulation 48. The cleaning process may comprise any process suitable for substantially removing accumulation 48 from reactor chamber 22, for example, a plasma clean process such as a fluorine-based plasma clean process. Plasma clean apparatus 28 introduces a cleaning gas 56 into reactor chamber 22 in order to substantially remove accumulation 48. Cleaning gas 56 may include a cleaning agent such as fluorine (F). Cleaning gas 56 reacts with accumulation 48 to substantially remove accumulation 48, and may also overetch surface 40, which may produce particles. As an example, overetching of an aluminum oxide coating of surface 40 with a fluorine-based cleaning gas may yield aluminum fluoride (AlF₃) particles.

According to the illustrated embodiment, plasma clean apparatus 28 includes a processor 50, a cleaning gas supply 52, and a mass-flow controller 54 coupled as illustrated in FIG. 1. Processor 50 manages the operations of system 10, cleaning gas supply 52 supplies the cleaning gas introduced into reactor chamber 22, and mass-flow controller 54 controls the flow of cleaning gas 56 in response to instructions from processor 50.

Processor 50 may manage the flow of cleaning gas 56 into reactor chamber 22, and may comprise any device operable to process input according to predefined rules to generate output such as a tool computer or external computing device. Cleaning gas 56 may comprise, for example, an ionized fluorine compound such as nitrogen trifluoride (NF₃) or other suitable chemical operable to remove accumulation 48. The volume of cleaning gas 56 introduced into reactor chamber 22 during the cleaning process typically affects the appropriate amount of cleaning of reactor chamber 22. If too little cleaning gas 56 is introduced into reactor chamber 22, accumulation 48 may remain disposed outwardly from surface 40. If too much cleaning gas 56 is introduced into reactor chamber 22, too many aluminum fluoride (AlF₃) particles may be generated, which may result in defects with the deposited layer.

Processor 50 may measure the volume of cleaning gas 56 introduced into reactor chamber 22 by, for example, establishing the volume of cleaning gas flowing per time unit, and then measuring the time in order to determine the volume of cleaning gas 56 introduced into reactor chamber 22. Other parameters that are substantially proportional to the volume of cleaning gas 56 introduced into reactor chamber 22 may be used to measure the volume of cleaning gas. As an example, a silane (SiH₄) plasma clean process time may be used.

Radio frequency power generating system 30 includes a radio frequency source 60 and a match 62. Radio frequency power generating system 30 generates radio frequency waves supplied to coil 42 of reactor chamber 22. Match 62 tunes the radio frequency to the appropriate frequency. The appropriate frequency is the frequency that may ionize the cleaning agent of cleaning gas 56 in order to remove accumulation 40 deposited outwardly from an inward surface of reactor chamber 22.

The cleaning process may result in the formation of particles such as aluminum fluoride (AlF₃) particles that may increase inline oxide defect density trends and chamber failures. Chamber maintenance may be performed. For example, parts of chemical vapor deposition systems such as aluminum oxide parts may be replaced in order to reduce or avoid these failures.

A technique for maintaining a reactor chamber 22 determines when chamber maintenance should be performed based on the number of wafers 44 processed by chemical vapor deposition system 20. The number of wafers, however, may not provide an accurate measure of the amount of cleaning performed or the total thickness of accumulation 48 cleaned by the process. As an example, thickness of an fluorinated silicate glass deposition may range from 1.5 kiloAngstroms to 12.5 kiloAngstroms. Typically, there is a cleaning cycle for every six micrometers of deposition. Accordingly, relying on the number of wafers processed may result in more inline oxide defect density trends and chamber failures.

The total volume of cleaning gas 56 introduced into reactor chamber 22 after one or more cleaning cycles may be used to schedule chamber maintenance that may be performed to reduce or avoid inline oxide defect density trends and chamber failures. When a predetermined volume of cleaning gas has been introduced into reactor chamber 22, chamber maintenance for maintaining and replacing parts may be scheduled. The predetermined volume may be determined from experimental results measuring how wafer quality, reflected by particle or defect densities, change with respect to the volume of cleaning gas. As an example, the predetermined volume may correspond to a maximum volume that may be introduced before wafer quality falls below a certain level. The chamber maintenance specification may be determined in accordance with device requirements in order to achieve certain target inline oxide defect densities and yield goals. As an example, larger semiconductor chips may require lower defect densities, so a tighter maintenance specification may be applied.

Modifications, additions, or omissions may be made to system 10 without departing from the scope of the invention. For example, system 10 may have more, fewer, or other modules. Moreover, the operations of system 10 may be performed by more, fewer, or other modules. For example, the operations of cleaning gas supply 52 and mass-flow controller 54 may be performed by one module, or the operations of processor 50 may be performed by more than one module. Additionally, functions may be performed using any suitable logic comprising software, hardware, other logic, or any suitable combination of the preceding. As used in this document, “each” refers to each member of a set or each member of a subset of a set.

FIG. 2 is a flowchart illustrating one embodiment of a method for maintaining a reactor chamber of a chemical vapor deposition system. The method begins at step 100, where an accumulation counter and a cleaning gas counter are initialized. The accumulation counter may be used to track the amount of deposition applied to processed wafers 44 in order to estimate the thickness of accumulation 48 on reactor chamber 22. The cleaning gas counter may be used to track the volume of cleaning gas 56 introduced into reactor chamber 22 during one or more successive cleaning cycles. Processor 50 may include the counters.

Wafer 44 is received at step 104. System 10 deposits a layer on wafer 44 at step 106. The layer may have a thickness of, for example, six kiloAngstroms. Wafer 44 is removed at step 108. The accumulation counter is updated at step 110 to reflect the thickness of the layer deposited on reactor chamber 22.

Processor 50 determines if the accumulation counter has reached a predetermined limit at step 112 that indicates that a plasma clean is to be performed. The maximum thickness may be approximately six microns, or any other thickness suitable for indicating that a plasma clean is to be performed. If the maximum thickness has not been reached, the method returns to step 104, where a next wafer 44 is received. If the maximum thickness has been reached at step 112, the method proceeds to step 114, where a plasma clean is performed. The accumulation counter is reset at step 116.

Processor 50 determines the volume of cleaning gas 56 that has been used to clean reactor chamber 22 and updates the cleaning gas counter at step 120. The volume of cleaning gas may be determined by, for example, the duration of the plasma clean and the volume of cleaning gas per time unit flowing into reactor chamber 22. Processor 50 determines if the cleaning gas counter indicates that the appropriate volume of cleaning gas has been reached at step 122. If the appropriate volume has not been reached at step 122, the method returns to step 104, where a next wafer 44 is received. If an appropriate volume has been reached at step 122, the method proceeds to step 124, where the chamber maintenance is scheduled. During the chamber maintenance, parts such as aluminum oxide parts of reactor chamber 22 may be replaced in order to reduce or eliminate particles that may result in wafer defects. After scheduling maintenance, the method terminates.

Modifications, additions, or omissions may be made to the method without departing from the scope of the invention. Additionally, steps may be performed in any suitable order without departing from the scope of the invention.

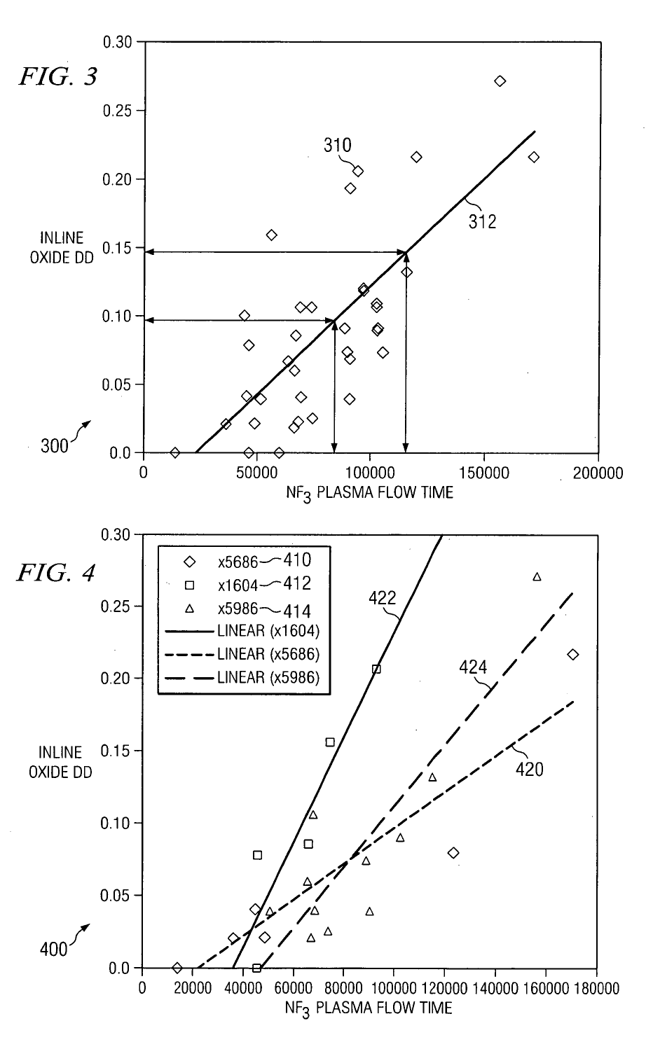

FIG. 3 is an example graph 300 indicating relative inline oxide defect densities (DD) with respect to the nitrogen trifluoride (NF₃) plasma flow time, as measured in seconds. A data point 310 represents a test instance having an inline oxide defect density at a particular nitrogen trifluoride (NF₃) plasma flow time. A line 312 indicates the best fit for data points 310.

FIG. 4 is an example graph 400 indicating relative inline oxide defect densities (DD) with respect to the nitrogen trifluoride (NF₃) plasma flow time, as measured in seconds. A data point 410 represents a test instance for a first device having a test inline oxide defect density at a particular nitrogen trifluoride (NF₃) plasma flow time, a data point 412 represents a test instance for a second device, and a data point 412 represents a test instance for a third device. Lines 420, 422, and 424 indicate the best fit for data points 410, 412, and 414, respectively.

Certain embodiments of the invention may provide one or more technical advantages. A technical advantage of one embodiment may be that the volume of cleaning gas introduced into a reactor chamber during one or more cleaning cycles may be used to schedule chamber maintenance. The volume of cleaning gas may provide a relatively accurate estimate of when the reactor chamber may need chamber maintenance.

Although an embodiment of the invention and its advantages are described in detail, a person skilled in the art could make various alterations, additions, and omissions without departing from the spirit and scope of the present invention as defined by the appended claims.

1. A method for maintaining a reactor chamber of a chemical vapor deposition system, comprising:
repeating the following until a volume of cleaning gas used during one or more plasma clean cycles has reached a predetermined volume:
depositing one or more layers outwardly from an inner surface of a reactor chamber of a chemical vapor deposition system, the one or more layers forming an accumulation layer;
establishing that the accumulation layer has reached a specified thickness;
performing a plasma clean cycle by introducing the cleaning gas into the reactor chamber; and
calculating the volume of the cleaning gas used during the one or more plasma clean cycles, the volume of the cleaning gas indicating the volume of cleaning gas introduced into the reactor chamber; and
providing a notification that the volume of the cleaning gas used during the one or more plasma clean cycles has reached the predetermined volume.

2. The method of claim 1, wherein depositing the one or more layers outwardly from the inner surface of the reactor chamber comprises repeating the following for one or more semiconductor wafers:
receiving a semiconductor wafer of the one or more semiconductor wafers; and
depositing a layer of the one or more layers on the received semiconductor wafer.

3. The method of claim 1, wherein depositing the one or more layers outwardly from the inner surface of the reactor chamber comprises repeating the following until the specified thickness is reached:
receiving a semiconductor wafer of one or more semiconductor wafers;
depositing a layer of the one or more layers on the received semiconductor wafer; and
calculating the thickness of the accumulation layer.

4. The method of claim 1, wherein calculating the volume of the cleaning gas used during the one or more plasma clean cycles comprises:
establishing a parameter related to the flow of the cleaning gas according to a mathematical relation;
measuring the parameter during the one or more plasma clean cycles to yield a measurement; and
calculating the volume of the cleaning gas in accordance with the measurement and the mathematical relation.

5. The method of claim 1, wherein calculating the volume of the cleaning gas used during the one or more plasma clean cycles comprises:
establishing a volume per time of the flow of the cleaning gas;
measuring the duration of the flow of the cleaning gas during the one or more plasma clean cycles to yield a measurement; and
calculating the volume of the cleaning gas in accordance with the measurement and the volume per time of the flow of the cleaning gas.

6. The method of claim 1, further comprising scheduling a chamber maintenance procedure in response to the notification that the volume of the cleaning gas used during the one or more plasma clean cycles has reached the predetermined volume.

7. A chemical vapor deposition system, comprising:
a plasma clean apparatus operable to repeat the following until a volume of cleaning gas used during one or more plasma clean cycles has reached a predetermined volume:
deposit one or more layers outwardly from an inner surface of a reactor chamber of a chemical vapor deposition system, the one or more layers forming an accumulation layer; and
perform a plasma clean cycle by introducing the cleaning gas into the reactor chamber when the accumulation layer has reached a specified thickness; and
a processor coupled to the plasma clean apparatus and operable to:
calculate the volume of the cleaning gas used during the one or more plasma clean cycles, the volume of the cleaning gas indicating the volume of cleaning gas introduced into the reactor chamber; and
provide a notification that the volume of the cleaning gas used during the one or more plasma clean cycles has reached the predetermined volume.

8. The system of claim 7, wherein the plasma clean apparatus is operable to deposit the one or more layers outwardly from the inner surface of the reactor chamber by repeating the following for one or more semiconductor wafers:
receiving a semiconductor wafer of the one or more semiconductor wafers; and
depositing a layer of the one or more layers on the received semiconductor wafer.

9. The system of claim 7, wherein the plasma clean apparatus is operable to deposit the one or more layers outwardly from the inner surface of the reactor chamber by repeating the following until the specified thickness is reached:
receiving a semiconductor wafer of one or more semiconductor wafers;
depositing a layer of the one or more layers on the received semiconductor wafer; and
calculating the thickness of the accumulation layer.

10. The system of claim 7, wherein the processor is operable to calculate the volume of the cleaning gas used during the one or more plasma clean cycles by:
establishing a parameter related to the flow of the cleaning gas according to a mathematical relation;
measuring the parameter during the one or more plasma clean cycles to yield a measurement; and
calculating the volume of the cleaning gas in accordance with the measurement and the mathematical relation.

11. The system of claim 7, wherein the processor is operable to calculate the volume of the cleaning gas used during the one or more plasma clean cycles by:
establishing a volume per time of the flow of the cleaning gas;
measuring the duration of the flow of the cleaning gas during the one or more plasma clean cycles to yield a measurement; and
calculating the volume of the cleaning gas in accordance with the measurement and the volume per time of the flow of the cleaning gas.

12. The system of claim 7, wherein the processor is further operable to schedule a chamber maintenance procedure in response to the notification that the volume of the cleaning gas used during the one or more plasma clean cycles has reached the predetermined volume.

13. Software for maintaining a reactor chamber of a chemical vapor deposition system, the software embodied in software and operable to:
repeat the following until a volume of cleaning gas used during one or more plasma clean cycles has reached a predetermined volume:
deposit one or more layers outwardly from an inner surface of a reactor chamber of a chemical vapor deposition system, the one or more layers forming an accumulation layer;
establish that the accumulation layer has reached a specified thickness;
perform a plasma clean cycle by introducing the cleaning gas into the reactor chamber; and
calculate the volume of the cleaning gas used during the one or more plasma clean cycles, the volume of the cleaning gas indicating the volume of cleaning gas introduced into the reactor chamber; and
provide a notification that the volume of the cleaning gas used during the one or more plasma clean cycles has reached the predetermined volume.

14. The software of claim 13, operable to deposit the one or more layers outwardly from the inner surface of the reactor chamber by repeating the following for one or more semiconductor wafers:
receiving a semiconductor wafer of the one or more semiconductor wafers; and
depositing a layer of the one or more layers on the received semiconductor wafer.

15. The software of claim 13, operable to deposit the one or more layers outwardly from the inner surface of the reactor chamber by repeating the following until the specified thickness is reached:
receiving a semiconductor wafer of one or more semiconductor wafers;
depositing a layer of the one or more layers on the received semiconductor wafer; and
calculating the thickness of the accumulation layer.

16. The software of claim 13, operable to calculate the volume of the cleaning gas used during the one or more plasma clean cycles by:
establishing a parameter related to the flow of the cleaning gas according to a mathematical relation;
measuring the parameter during the one or more plasma clean cycles to yield a measurement; and
calculating the volume of the cleaning gas in accordance with the measurement and the mathematical relation.

17. The software of claim 13, operable to calculate the volume of the cleaning gas used during the one or more plasma clean cycles by:
establishing a volume per time of the flow of the cleaning gas;
measuring the duration of the flow of the cleaning gas during the one or more plasma clean cycles to yield a measurement; and
calculating the volume of the cleaning gas in accordance with the measurement and the volume per time of the flow of the cleaning gas.

18. The software of claim 13, further operable to schedule the chamber maintenance procedure in response to the notification that the volume of the cleaning gas used during the one or more plasma clean cycles has reached the predetermined volume.

19. A system for maintaining a reactor chamber of a chemical vapor deposition system, comprising:
means for repeating the following until a volume of cleaning gas used during one or more plasma clean cycles has reached a predetermined volume:
depositing one or more layers outwardly from an inner surface of a reactor chamber of a chemical vapor deposition system, the one or more layers forming an accumulation layer;
establishing that the accumulation layer has reached a specified thickness;
performing a plasma clean cycle by introducing the cleaning gas into the reactor chamber; and
calculating the volume of the cleaning gas used during the one or more plasma clean cycles, the volume of the cleaning gas indicating the volume of cleaning gas introduced into the reactor chamber; and
means for providing a notification that the volume of the cleaning gas used during the one or more plasma clean cycles has reached the predetermined volume.

20. A method for maintaining a reactor chamber of a chemical vapor deposition system, comprising:
repeating the following until a volume of cleaning gas used during one or more plasma clean cycles has reached a predetermined volume:
depositing one or more layers outwardly from an inner surface of a reactor chamber of a chemical vapor deposition system, the one or more layers forming an accumulation layer, by:
repeating the following for one or more semiconductor wafers: receiving a semiconductor wafer of the one or more semiconductor wafers, and depositing a layer of the one or more layers on the received semiconductor wafer; and
repeating the following until the specified thickness is reached: receiving a semiconductor wafer of the one or more semiconductor wafers, depositing a layer of the one or more layers on the received semiconductor wafer, and calculating the thickness of the accumulation layer;
establishing that the accumulation layer has reached a specified thickness;
performing a plasma clean cycle by introducing the cleaning gas into the reactor chamber; and
calculating the volume of the cleaning gas used during the one or more plasma clean cycles, the volume of the cleaning gas indicating the volume of cleaning gas introduced into the reactor chamber, by:
establishing a parameter related to the flow of the cleaning gas according to a mathematical relation, measuring the parameter during the one or more plasma clean cycles to yield a measurement, and calculating the volume of the cleaning gas in accordance with the measurement and the mathematical relation;
establishing a volume per time of the flow of the cleaning gas, measuring the duration of the flow of the cleaning gas during the one or more plasma clean cycles to yield a time measurement, and calculating the volume of the cleaning gas in accordance with the time measurement and the volume per time of the flow of the cleaning gas;
providing a notification that the volume of the cleaning gas used during the one or more plasma clean cycles has reached the predetermined volume; and
scheduling the chamber maintenance procedure in response to the notification that the volume of the cleaning gas used during the one or more plasma clean cycles has reached the predetermined volume.
